(19) United States
(12) Patent Application Publication
(10) Pub. No.: US 2013/0135395 A1
(43) Pub. Date: May 30, 2013

(54) SILICON SUBSTRATE, METHOD OF MANUFACTURING THE SAME, AND INKJET PRINT HEAD

(71) Applicants: Jae Chang LEE, Osan (KR); Tae Kyung Lee, Suwon (KR); Hwa Sun Lee, Hwaseong (KR); Sung Wook Kim, Suwon (KR)

(72) Inventors: Jae Chang LEE, Osan (KR); Tae Kyung Lee, Suwon (KR); Hwa Sun Lee, Hwaseong (KR); Sung Wook Kim, Suwon (KR)

(73) Assignee: Samsung Electro-Mechanics Co., Ltd., Suwon (KR)

(21) Appl. No.: 13/572,018

(22) Filed: Aug. 10, 2012

(30) Foreign Application Priority Data
Nov. 30, 2011 (KR) 10-2011-0126591

(51) Int. Cl. B41J 2/04; H01L 21/306

(52) U.S. Cl. 347/54; 438/21; 257/E21.219

(57) ABSTRACT

There is provided a silicon substrate including: a first connection part connected to a manifold and having a first width of a first size; a second connection part connected to a pressure chamber and having a second width of a second size; and a restrictor part connecting the first connection part to the second connection part and having a third width of a third size smaller than the first size or the second size, wherein a boundary part connecting the restrictor part to the first connection part or the restrictor part to the second connection part is formed to be curved.

### CROSS-REFERENCE TO RELATED APPLICATIONS

This application claims the priority of Korean Patent Application No. 10-2011-0126591 filed on Nov. 30, 2011, in the Korean Intellectual Property Office, the disclosure of which is incorporated herein by reference.

### BACKGROUND OF THE INVENTION

1. Field of the Invention

The present invention relates to a silicon substrate in which a restrictor is formed, a method of manufacturing the same, and an inkjet print head, and more particularly, to a silicon substrate having a flow path structure allowing for a smooth flow of ink, a method of manufacturing the same, and an inkjet print head including the same.

2. Description of the Related Art

An inkjet print head is an apparatus for converting an electrical signal into a physical impulse and ejecting droplets of stored ink

As an inkjet print head may be manufactured in mass production, it is used not only for printers for office but also for industrial printers. For example, the inkjet print head is used not only in offices for printing out documents by ejecting ink on paper but also in factories where circuit patterns are produced directly by ejecting a liquid metal material to a printed circuit board (PCB).

A general inkjet print head may include a plurality of pressure chambers and a plurality of nozzles. The inkjet print head may simultaneously eject monochromatic ink or multiple colors of ink through the plurality of nozzles, thereby not only increasing a printing speed thereof but also enabling vivid printing.

Meanwhile, an inkjet print head may have a structure in which a plurality of substrates are stacked. This inkjet print head may form a path through which ink flows by stacking upper and lower substrates in which a manifold, a restrictor, a pressure chamber and the like are formed.

However, a conventional inkjet print head may have a manifold, a restrictor, a pressure chamber and the like formed therein through dry etching, which may cause defects therein, due to the presence of particles during a photo process or an etching process using an oxide film as a mask.

Therefore, in the formation of the conventional inkjet print head, the probability of defects in the ink flow path being formed from the manifold to the pressure chamber may be increased, thereby reducing a manufacturing yield thereof.

### SUMMARY OF THE INVENTION

An aspect of the present invention provides a silicon substrate having a restrictor formed therein, allowing for a smooth flow of ink by removing the possibility of defects likely to occur during a process of manufacturing a conventional inkjet print head, a method of manufacturing the same, and an inkjet print head including the same.

According to an aspect of the present invention, there is provided a silicon substrate including: a first connection part connected to a manifold and having a first width of a first size; a second connection part connected to a pressure chamber and having a second width of a second size; and a restrictor part connecting the first connection part to the second connection part and having a third width of a third size smaller than the first size or the second size, wherein a boundary part connecting the restrictor part to the first connection part or the restrictor part to the second connection part is formed to be curved.

The first connection part may have a cross-sectional shape corresponding to that of the manifold.

The first connection part may have a cross-sectional shape smaller than that of the manifold.

The silicon substrate may further include a nozzle part formed to be spaced apart from the second connection part by a predetermined distance.

The boundary part may be formed by wet etching.

The first connection part, the second connection part, and the restrictor part may be formed to extend in a thickness direction of the silicon substrate.

According to another aspect of the present invention, there is provided a method of manufacturing a silicon substrate, the method including: forming a first developing pattern having a first width of a first size and a second developing pattern having a second width of a second size on one surface of the silicon substrate; forming a third developing pattern between the first developing pattern and the second developing pattern, the third developing pattern having a third width of a third size smaller than the first size and the second size; developing, removing, and dry etching the first to third developing patterns and forming etched parts corresponding to the first through third developing patterns; and wet etching the silicon substrate to thereby complete shapes of the etched parts.

The third developing pattern may be formed to have a distance of a fourth size from the first and second developing patterns.

The fourth size may be smaller than the third size.

The fourth size may be smaller than a thickness of the silicon substrate.

The wet etching may be performed using TMAH or KOH (potassium hydroxide).

The first developing pattern may form a first connection part connected to a manifold, the second developing pattern may form a second connection part connected to a pressure chamber, and the third developing pattern may form a restrictor part.

According to another aspect of the present invention, there is provided an inkjet print head including: a first substrate in which a manifold and a pressure chamber are formed; and a second substrate in which a first connection part connected to the manifold, a second connection part connected to the pressure chamber, and a restrictor part connecting the first connection part and the second connection part are formed, wherein a boundary part connecting the restrictor part to the first connection part or the restrictor part to the second connection part is formed to be curved.

The inkjet print head may further include a nozzle part formed to be spaced apart from the second connection part by a predetermined distance.

The second substrate may be formed by dry etching and wet etching.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a plan view of a silicon substrate according to a first embodiment of the present invention;

FIG. 2 is a cross-sectional view of the silicon substrate of FIG. 1 taken along line A-A;

FIG. 3 is a cross-sectional view of an inkjet print head including the silicon substrate of FIG. 1 according to the first embodiment of the present invention;

FIG. 4 is a plan view of a silicon substrate according to a second embodiment of the present invention;

FIG. 5 is a cross-sectional view of an inkjet print head including the silicon substrate of FIG. 4 according to the second embodiment of the present invention;

FIG. 6 is a plan view of a silicon substrate according to a third embodiment of the present invention;

FIG. 7 is a cross-sectional view of an inkjet print head including the silicon substrate of FIG. 6 according to the third embodiment of the present invention;

FIG. 8 is a view illustrating a method of manufacturing a silicon substrate according to an embodiment of the present invention; and

FIGS. 9 through 14 are experimental images showing the etched states of a silicon substrate by a method of manufacturing a silicon substrate according to an embodiment of the present invention.

### DETAILED DESCRIPTION OF THE EMBODIMENTS

Hereinafter, embodiments of the present invention will be described in detail with reference to the accompanying drawings.

In describing the present invention below, terms indicating components of the present invention are named in consideration of functions thereof. Therefore, the terms should not be understood as limiting technical components of the present invention.

A silicon substrate forming an inkjet print head may include a manifold, a pressure chamber, a restrictor, and the like.

In this regard, the manifold, the pressure chamber, the restrictor, and the like may be formed by developing, removing, and etching processes of a PR pattern.

However, since the developed PR pattern cannot be completely removed from the silicon substrate, the manifold, the pressure chamber, the restrictor, and the like may not be exactly formed during the etching process of the PR pattern.

Defects in the formation of the manifold, the pressure chamber, and the restrictor may hinder ink flow, which makes it difficult for the inkjet print head to precisely eject ink.

To solve this problem, the present invention provides a silicon substrate having improvements in a flow path of ink, a method of manufacturing the silicon substrate, and an inkjet print head including the silicon substrate.

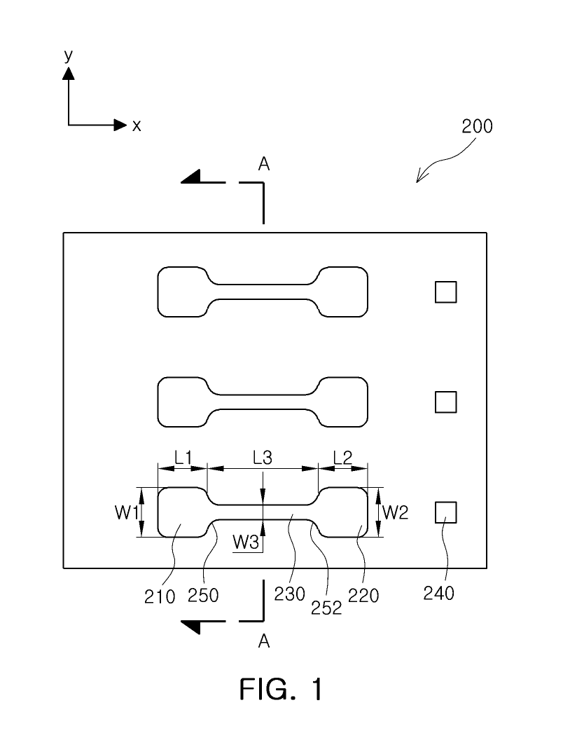

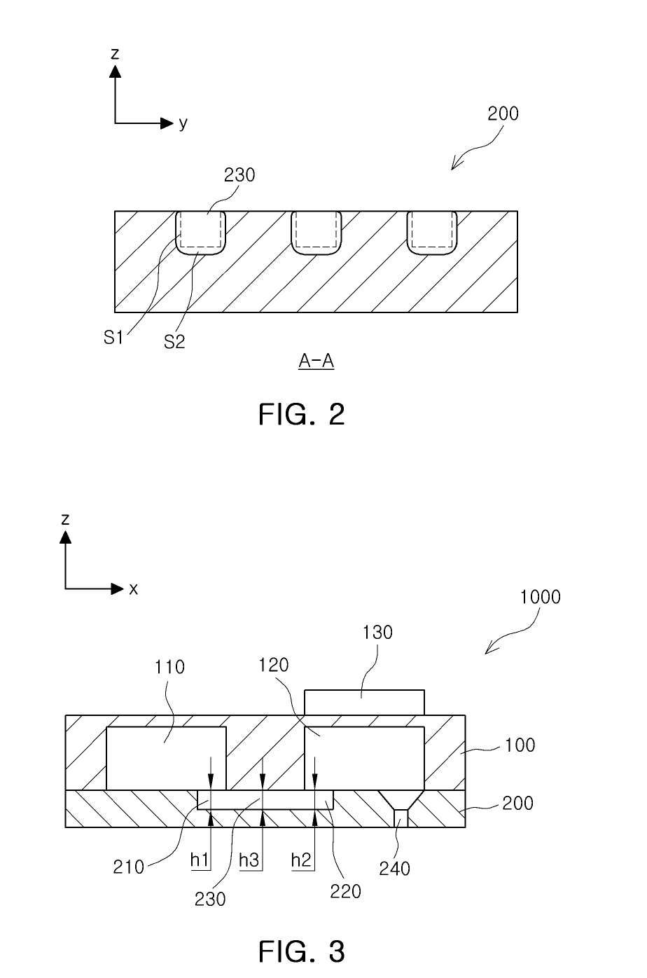

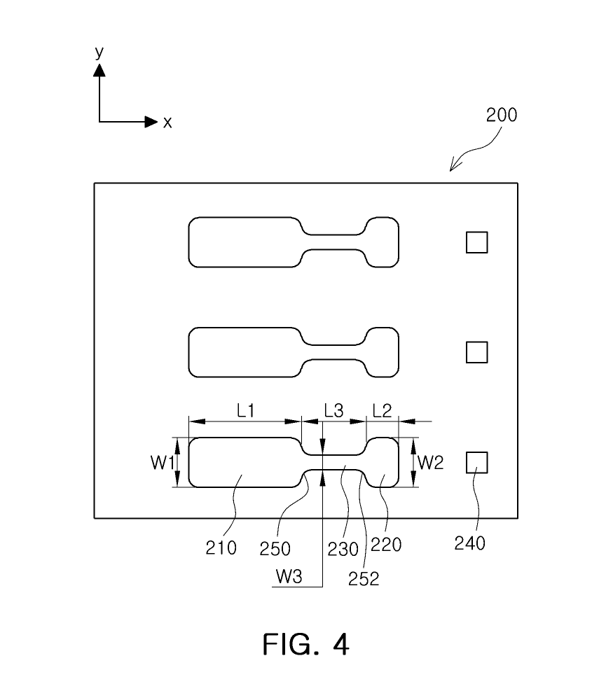

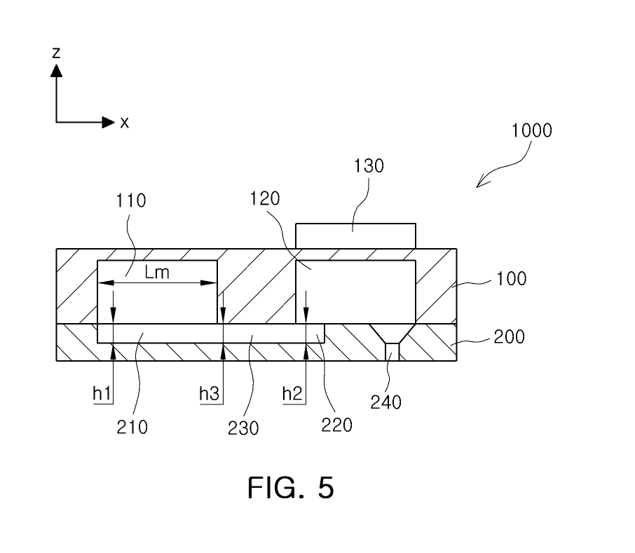

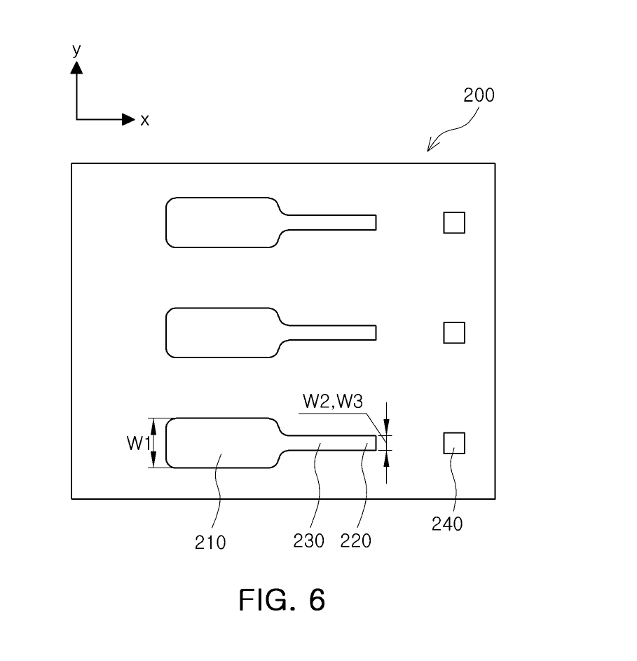

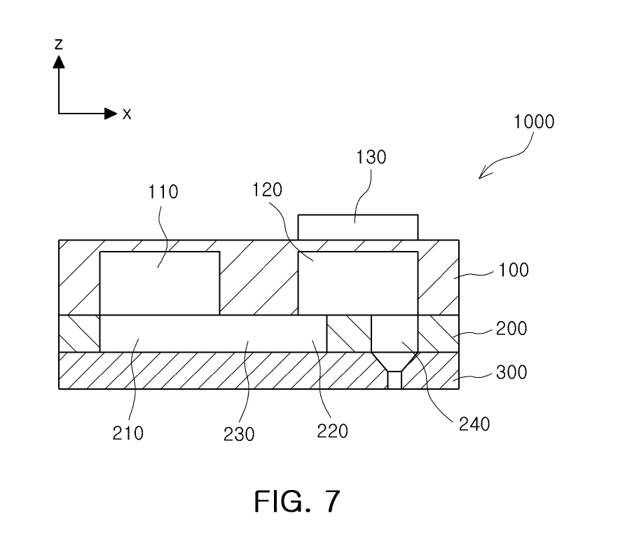

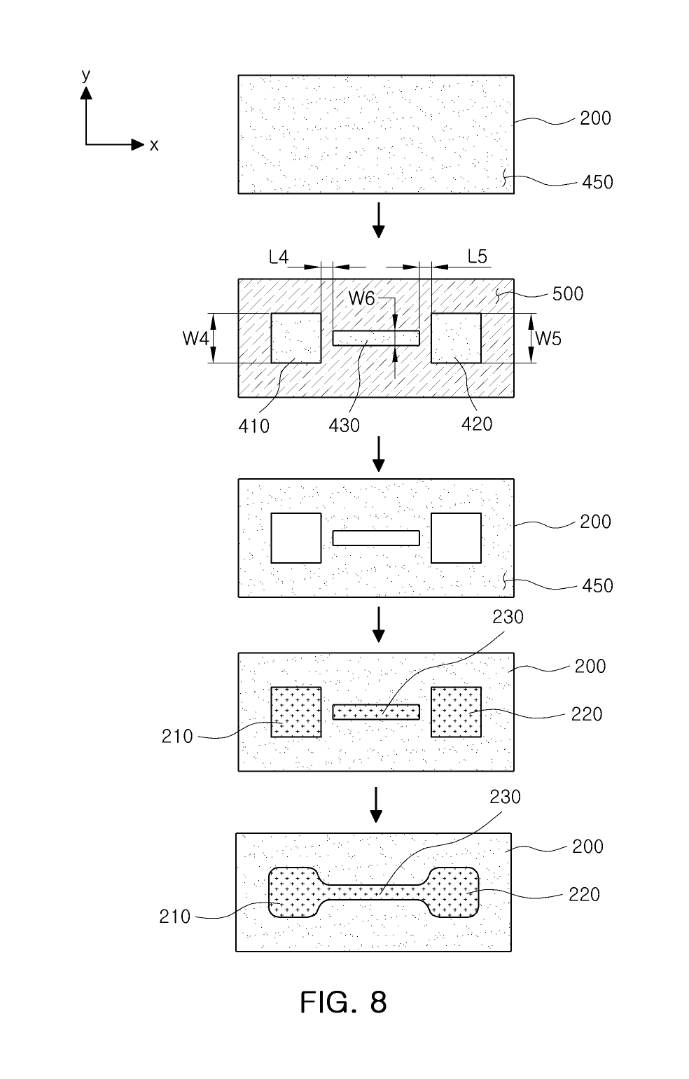

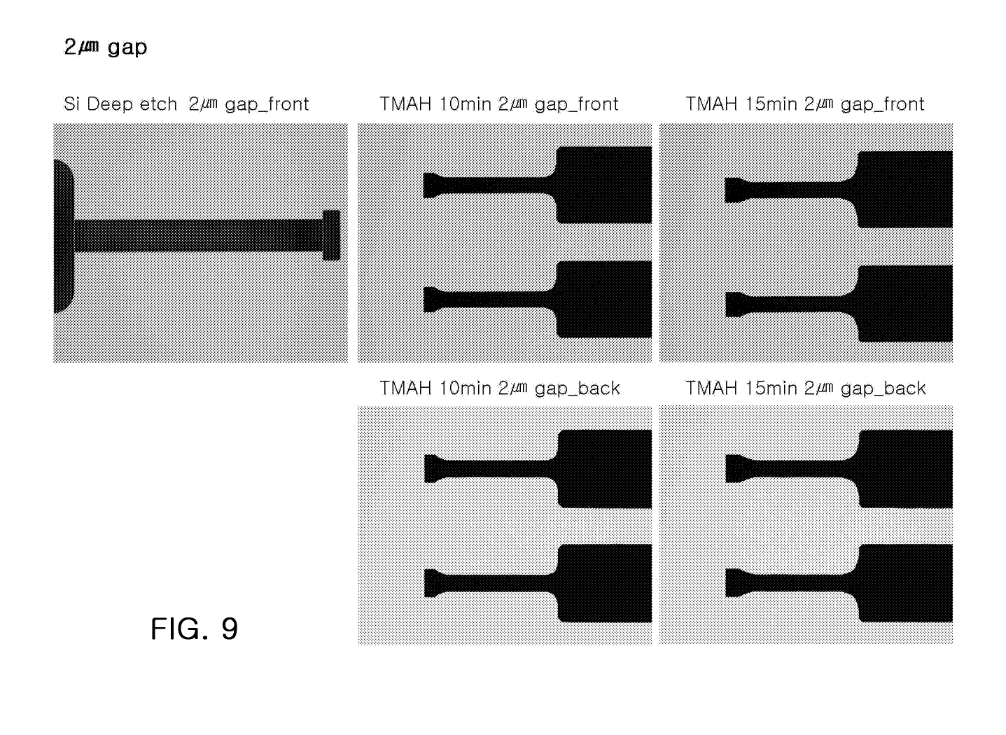

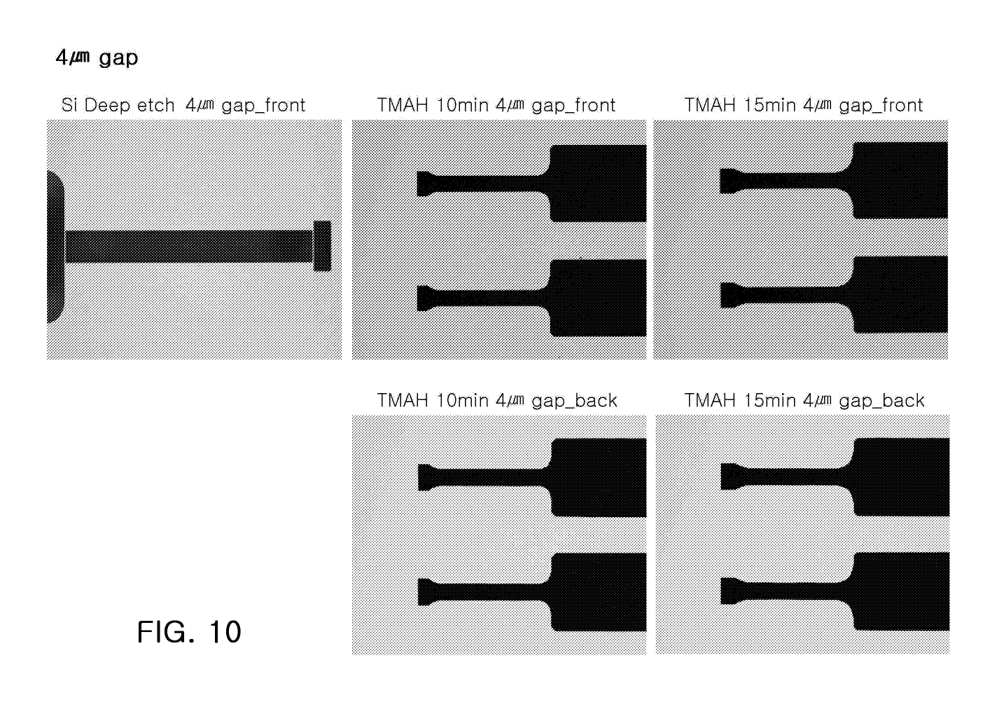

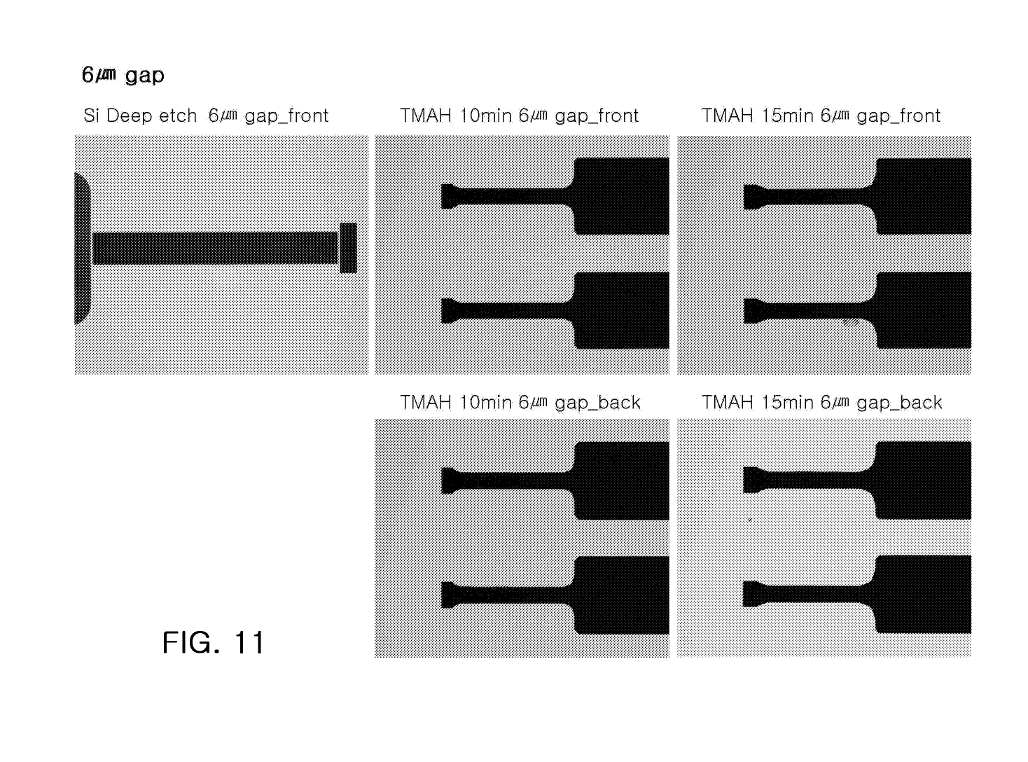

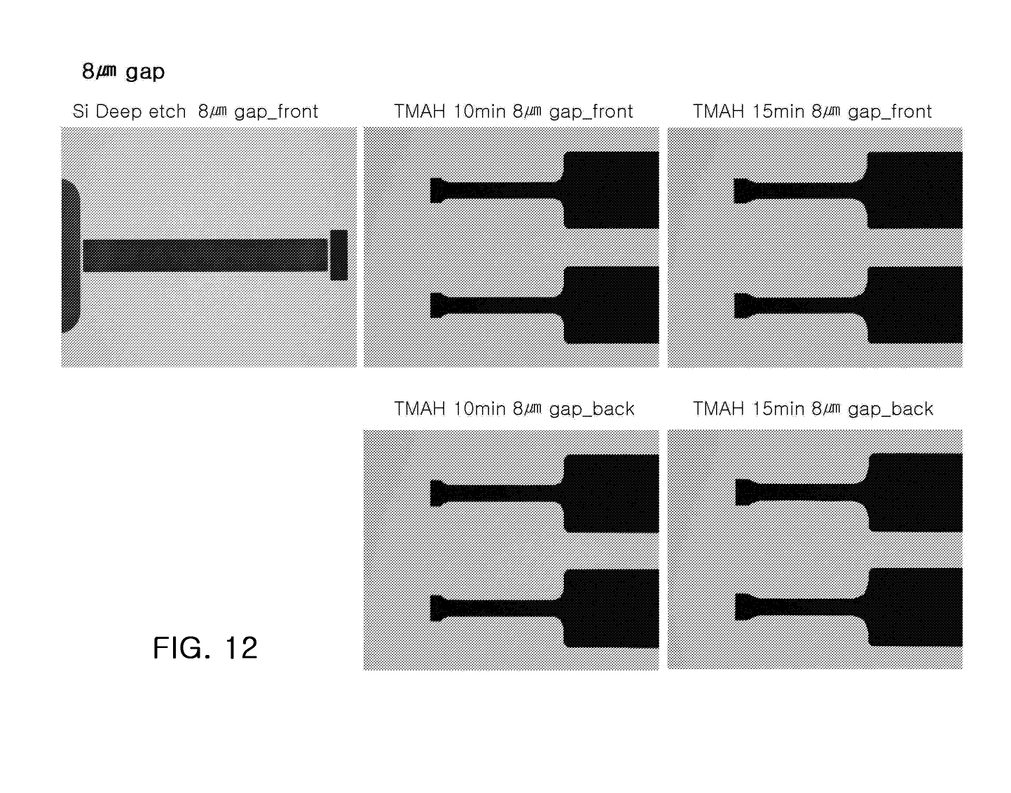

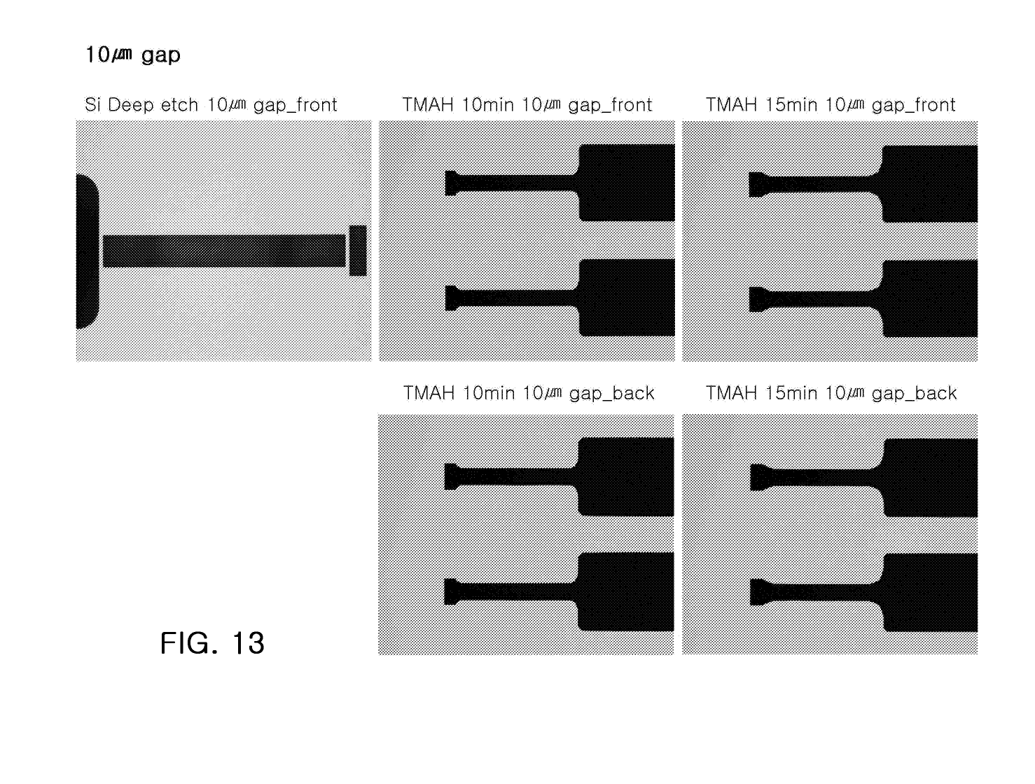

FIG. 1 is a plan view of a silicon substrate according to a first embodiment of the present invention. FIG. 2 is a cross-sectional view of the silicon substrate of FIG. 1 taken along line A-A. FIG. 3 is a cross-sectional view of an inkjet print head including the silicon substrate of FIG. 1 according to the first embodiment of the present invention. FIG. 4 is a plan view of a silicon substrate according to a second embodiment of the present invention. FIG. 5 is across-sectional view of an inkjet print head including the silicon substrate of FIG. 4 according to the second embodiment of the present invention. FIG. 6 is a plan view of a silicon substrate according to a third embodiment of the present invention. FIG. 7 is a cross-sectional view of an inkjet print head including the silicon substrate of FIG. 6 according to the third embodiment of the present invention. FIG. 8 is a view illustrating a method of manufacturing a silicon substrate according to an embodiment of the present invention. FIGS. 9 through 14 are experimental images showing the etched states of a silicon substrate by a method of manufacturing a silicon substrate according to an embodiment of the present invention.

A silicon substrate 200 and an inkjet print head according to a first embodiment of the present invention will now be described with reference to FIGS. 1 through 3.

The silicon substrate 200 may form part of the inkjet print head. For example, the silicon substrate 200 may be a first substrate including a manifold and a pressure chamber of the inkjet print head, or a second substrate including a restrictor and a nozzle thereof. Alternatively, the silicon substrate 200 may be an intermediate substrate disposed between the first substrate and the second substrate.

The silicon substrate 200 may be a monocrystalline silicon substrate. However, a second substrate 200 may be asilicon on insulator (SOI) substrate as occasion demands. In this case, the second substrate 200 may be a stack structure in which a silicon substrate and a plurality of insulation members are stacked.

The silicon substrate 200 may include a first connection part 210, a second connection part 220, and a restrictor part 230. The silicon substrate 200 may further include a nozzle part 240. The first connection part 210, the second connection part 220, the restrictor part 230, and the nozzle part 240 may be sequentially formed in a first direction (in an X-axis direction in FIG. 1) of the silicon substrate 200. In addition, the first connection part 210, the second connection part 220, the restrictor part 230, and the nozzle part 240 may be arranged in a plurality of rows, each row having a predetermined interval therebetween in a second direction (in a Y-axis direction in FIG. 1) of the silicon substrate 200.

The silicon substrate 200 formed as described above may be provided as the second substrate in the inkjet print head.

The first connection part 210 may form part of the manifold or may be connected to the manifold. To this end, the first connection part 210 may have a first width W1 of a first size, a predetermined first length L1, and a predetermined first depth h1 (see FIG. 3). Here, the first width W1 may be equal to a width of the manifold, and the first length L1 may be smaller than a length of the manifold.

The second connection part 220 may form part of the pressure chamber or may be connected to the pressure chamber. To this end, the second connection part 220 may have a second width W2 of a second size, a predetermined second length L2, and a predetermined second depth h2 (see FIG. 3). Here, the second width W2 may be equal to a width of the pressure chamber, and may be equal to or smaller than the first width W1. In addition, the second length L2 may be smaller than a length of the pressure chamber, and the second depth h2 may be equal to the first depth h1.

The restrictor part 230 may form the restrictor in the inkjet print head. To this end, the restrictor part 230 may have a third width W3 of a third size smaller than the first width W1 or the second width W2. In addition, the restrictor part 230 may have a predetermined third length L3 to delay a flow speed of ink moving from the first connection part 210 to the second connection part 220.

The restrictor part 230 may be connected to the first connection part 210 and the second connection part 220. Here, boundary parts 250 and 252 to which the restrictor part 230 and the first and second connection parts 210 and 220 are substantially connected may be curved. That is, the boundary parts 250 and 252 may be curved such that ink can smoothly flow from the first connection part 210 to the second connection part 220. The boundary parts 250 and 252 having the above-described shapes may reduce resistance to ink, thereby remarkably reducing a foam generation phenomenon due to a rapid flow of ink.

Therefore, according to the present embodiment, the deterioration of printing quality due to foams may be effectively reduced.

Meanwhile, the shapes of the boundary parts 250 and 252 may be formed by wet etching. Wet etching may be performed in a 3D manner, unlike dry etching performed in a planar manner. Thus, wet etching may change the boundary parts 250 and 252 to have curved shapes. Wet etching may also extend a cross-sectional shape of the restrictor part 230 and simultaneously change it smoothly.

For example, S1 of FIG. 2 is a cross-sectional shape of the restrictor part 230 formed by dry etching, whereas S2 may be a cross-sectional shape of the restrictor part 230 formed by wet etching.

The cross-section of the restrictor part 230 may be secondarily processed with wet etching, thereby completely removing parts that are not removed by dry etching.

The nozzle part 240 may be formed to have a distance from the second connection part 220. The nozzle part 240 may be connected to the pressure chamber, and may be used as a nozzle ejecting ink stored in the pressure chamber.

The above-described silicon substrate 200 may form part of an inkjet print head 1000 as shown in FIG. 3. For reference, the silicon substrate 200 may be referred to as a second substrate in the description of FIG. 3.

The inkjet print head 1000 of FIG. 3 may include a first substrate 100 and the second substrate 200.

The first substrate 100 may form part of the inkjet print head 1000, and may be a monocrystalline silicon substrate.

However, the first substrate 100 may be a SOI substrate as occasion demands. In this case, the first substrate 100 may be a stack structure in which a silicon substrate and a plurality of insulation members are stacked.

The first substrate 100 may include a manifold 110, a pressure chamber 120, and an actuator 130. More specifically, the manifold 110 and the pressure chamber 120 may be formed in one surface (a bottom surface in FIG. 3) of the first substrate 100, and the actuator 130 may be formed in the other surface (a top surface in FIG. 3) thereof. In addition, although not shown in FIG. 3, an ink supply path connected to the manifold 110 may be formed in the first substrate 100.

The manifold 110 may be formed in the bottom surface of the first substrate 100. The manifold 110 may be elongated in the X-axis direction having a predetermined interval with respect to the pressure chamber 120.

The manifold 110 may be formed to partially overlap the first connection part 210 of the second substrate 200. More specifically, the manifold 110 may be connected to the first connection part 210 when the first substrate 100 and the second substrate 200 are coupled to each other. In addition, the manifold 110 may be connected to the ink supply path to supply stored ink to the pressure chamber 120.

The pressure chamber 120 may be formed in the bottom surface of the first substrate 100.

The pressure chamber 120 may be formed to overlap the second connection part 220 and the nozzle part 240 of the second substrate 200. More specifically, the pressure chamber 120 may be connected to the second connection part 220 and the nozzle part 240 when the first substrate 100 and the second substrate 200 are coupled to each other.

The pressure chamber 120 may have a predetermined volume. More specifically, the volume of the pressure chamber 120 may be equal to or greater than the volume of ink droplets to be ejected by a single operation of the actuator 130. Here, the former may be preferable to a quantitative ejection of ink, and the latter may be preferable to a continuous ejection from the inkjet print head 1000.

The actuator 130 may be formed on the top surface of the first substrate 100. More specifically, the actuator 130 may be formed on a portion of the top surface of the first substrate 100 corresponding to the pressure chamber 120.

The actuator 130 may include a piezoelectric element and upper and lower electrode members. More specifically, the actuator 130 may be a stacked structure in which the piezoelectric element is disposed between the upper and lower electrode members.

The actuator 130 formed as described above may extend and contract according to an electrical signal and provide pressure to the pressure chamber 120.

The second substrate 200 may form the remaining part of the inkjet print head 1000.

The second substrate 200 may include the first connection part 210, the second connection part 220, the restrictor part 230, and the nozzle part 240.

Here, the first connection part 210 may be connected to the manifold 110, and the second connection part 220 may be connected to the pressure chamber 120. The restrictor part 230 may connect the first connection part 210 and the second connection part 220, and form a flow path connecting the manifold 110 and the pressure chamber 120.

The inkjet print head 1000 formed as described above includes a flow path of ink having no defects (for example, parts that are not completely removed by dry etching) as described with reference to the second substrate 200, thereby quantitatively ejecting ink and obtaining uniform printing quality.

A silicon substrate and an inkjet print head according to a second embodiment of the present invention will now be described with reference to FIGS. 4 and 5.

The silicon substrate 200 according to the second embodiment may be distinguishable from the silicon substrate 200 according to the first embodiment in that the first length L1 of the first connection part 210 is equal to the length of the manifold 110.

The first connection part 210 according to the present embodiment may have a first length L1 equal to a length Lm of the manifold 110. In addition, the first connection part 210 may form part of the manifold 110.

The above-described inkjet print head 1000 may allow for the forming of the manifold 110 having a relatively large volume.

A silicon substrate and an inkjet print head according to a third embodiment of the present invention will now be described with reference to FIGS. 6 and 7.

The silicon substrate 200 according to the third embodiment may be distinguishable from the silicon substrate according to the first and second embodiments in that the second connection part 220 and the restrictor part 230 are integrally formed.

That is, the second connection part 220 in the present embodiment may have a second width W2 equal to a third width W3 of the restrictor part 230. Alternatively, the second connection part 220 may be omitted. In this case, the restrictor part 230 may be connected to the pressure chamber 120. Here, the second width W2 may be smaller than the width of the pressure chamber 120.

The silicon substrate 200 having the above-described shape may have a relatively small width of an ink flow path extending from the pressure chamber 120 to the restrictor part 230, thereby effectively preventing ink from flowing backwards.

In addition, the inkjet print head 1000 according to the present embodiment may include three substrates 100, 200, and 300 as shown in FIG. 7. However, this is exemplary, and the number of substrates may increase or decrease as occasion demands.

A method of manufacturing a silicon substrate according to an embodiment of the present invention will now be described with reference to FIG. 8.

The method of manufacturing the silicon substrate according to this embodiment of the invention may include forming an oxide film 450, forming PR patterns 410, 420, and 430, firstly etching the oxide film 450 and the silicon substrate 200, removing a PR layer 500, and secondly etching the silicon substrate 200.

### 1) Formation of Oxide Film

The oxide film 450 may be formed on the silicon substrate 200.

The oxide film 450 may be formed on one surface or both surfaces of the silicon substrate 200. Alternatively, the oxide film 450 may be formed on the overall surface of the silicon substrate 200. The oxide film 450 may be formed through thin film sputtering. However, this is an exemplary method, and the oxide film 450 may be formed using another method.

### 2) Formation of PR Patterns

The PR patterns 410, 420, and 430 may be formed on the silicon substrate 200. More specifically, the PR layer 500 may be formed on the oxide film 450.

The PR layer 500 may include the PR patterns 410, 420, and 430 through developing and removal processes. The PR patterns 410, 420, and 430 may be formed using a mask.

The shapes of the PR patterns 410, 420, and 430 may correspond to those of the first and second connection parts 210 and 220 and the restrictor part 230 of the silicon substrate 200 shown in FIG. 1.

For example, the first PR pattern 410 may correspond to the first connection part 210 and may have a fourth width W4. Here, a size of the fourth width W4 may be equal to or smaller than that of the first width W1.

The second PR pattern 420 may correspond to the second connection part 220 and may have a fifth width W5. Here, a size of the fifth width W5 may be equal to or smaller than that of the second width W2. The second PR pattern 420 may be formed to have a significant distance from the first PR pattern 410.

The third PR pattern 430 may correspond to the restrictor part 230, and may have a sixth width W6. Here, a size of the sixth width W6 may be equal to or smaller than that of the third width W3.

Meanwhile, the third PR pattern 430 may be formed between the first PR pattern 410 and the second PR pattern 420. The third PR pattern 430 may be formed to have distances L4 and L5 from the first PR pattern 410 and the second PR pattern 420. Here, the distances L4 and L5 may be smaller than the sixth width W6 of the third PR pattern 430.

### 3) Primary Etching Operation

The oxide film 450 and the silicon substrate 200 may be etched.

More specifically, the oxide film 450 and the silicon substrate 200 exposed by the PR patterns 410, 420, and 430 may be etched by dry etching. In this operation, the first and second connection parts 210 and 220, the restrictor part 230, and the nozzle part 240 may be formed in the silicon substrate 200. However, the first and second connection parts 210 and 220, the restrictor part 230, and the nozzle part 240 may have the same shapes as those of the PR patterns 410, 420, and 430. That is, the first and second connection parts 210 and 220, the restrictor part 230, and the nozzle part 240 may be formed to be separated from each other.

### 4) Removal of PR Layer

The PR layer 500 may be removed from the silicon substrate 200.

The PR layer 500 may be removed by using a separate etching liquid or a separate tool.

### 5) Secondary Etching Operation

During this operation, an ink flow path may be completely formed in the silicon substrate 200. The silicon substrate 200 may be subjected to wet etching.

Wet etching is performed on a portion of the silicon substrate 200 in which the oxide film 450 is not formed, and thus, side portions of the first and second connection parts 210 and 220 and the restrictor part 230 may be extended, thereby removing defects therefrom.

In addition, wet etching may allow for the connection of the first connection part 210 and the restrictor part 230, and the connection of the second connection part 220 and the restrictor part 230. Wet etching may be performed by using TMAH or KOH (potassium hydroxide).

The above-described method of manufacturing the silicon substrate 200 may remove parts that are not completely etched by dry etching and allow corner parts to be curved.

According to the experiment, wet etching was performed to etch side walls of the parts formed by dry etching, thereby increasing cross-sections thereof and allowing for the connections of the separated parts (see FIGS. 9 through 13).

That is, parts corresponding to the shapes of the first connection part 210, the restrictor part 230, and the second connection part 220 in the silicon substrate 200 were formed through dry etching. Here, the first connection part 210, the restrictor part 230, and the second connection part 220 were formed to have a predetermined distance therebetween. More specifically, the experiment was conducted by changing the distance to 2 μm, 4 μm, 6 μm, 8 μm, and 10 μm.

Thereafter, wet etching was performed on the silicon substrate 200 during a predetermined period of time. As a result, the first connection part 210, the restrictor part 230, and the second connection part 220 formed with the predetermined distance therebetween were connected after the predetermined period of time as shown in FIGS. 9 through 13.

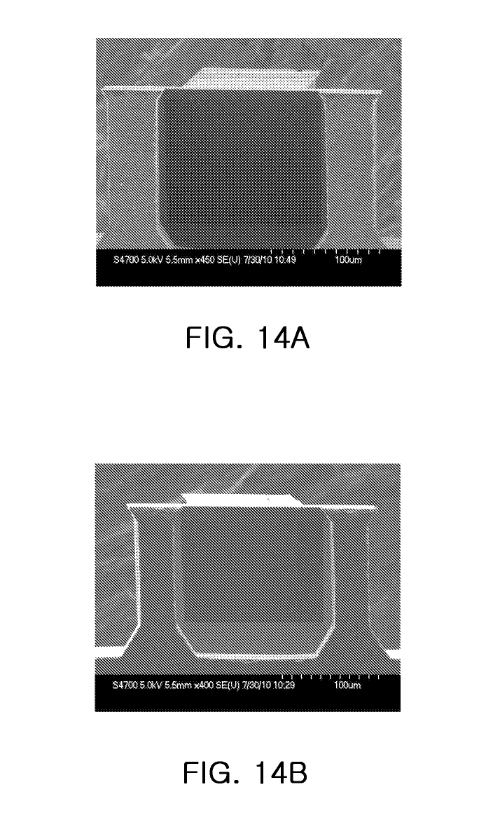

In particular, according to this experiment, wet etching performed after dry etching could allow for the connections of the first connection part 210, the restrictor part 230, and the second connection part 220 while having curved shapes, and could clearly process the cross-section of the restrictor part 230 as shown in FIG. 14.

As set forth above, according to embodiments of the present invention, defects in etched state that may occur during a dry etching process of a silicon substrate may be effectively prevented, whereby ink flow can be improved.

Therefore, according to embodiments of the present invention, a manufacturing yield of an inkjet print head can be enhanced.

While the present invention has been shown and described in connection with the embodiments, it will be apparent to those skilled in the art that modifications and variations can be made without departing from the spirit and scope of the invention as defined by the appended claims.

What is claimed is:

1. A silicon substrate comprising:
a first connection part connected to a manifold and having a first width of a first size;
a second connection part connected to a pressure chamber and having a second width of a second size; and
a restrictor part connecting the first connection part to the second connection part and having a third width of a third size smaller than the first size or the second size,
wherein a boundary part connecting the restrictor part to the first connection part or the restrictor part to the second connection part is formed to be curved.

2. The silicon substrate of claim 1, wherein the first connection part has a cross-sectional shape corresponding to that of the manifold.

3. The silicon substrate of claim 1, wherein the first connection part has a cross-sectional shape smaller than that of the manifold.

4. The silicon substrate of claim 1, further comprising a nozzle part formed to be spaced apart from the second connection part by a predetermined distance.

5. The silicon substrate of claim 1, wherein the boundary part is formed by wet etching.

6. The silicon substrate of claim 1, wherein the first connection part, the second connection part, and the restrictor part are formed to extend in a thickness direction of the silicon substrate.

7. A method of manufacturing a silicon substrate, the method comprising:
forming a first developing pattern having a first width of a first size and a second developing pattern having a second width of a second size on one surface of the silicon substrate;
forming a third developing pattern between the first developing pattern and the second developing pattern, the third developing pattern having a third width of a third size smaller than the first size and the second size;
developing, removing, and dry etching the first to third developing patterns and forming etched parts corresponding to the first through third developing patterns; and
wet etching the silicon substrate to thereby complete shapes of the etched parts.

8. The method of claim 7, wherein the third developing pattern is formed to have a distance of a fourth size from the first and second developing patterns.

9. The method of claim 8, wherein the fourth size is smaller than the third size.

10. The method of claim 8, wherein the fourth size is smaller than a thickness of the silicon substrate.

11. The method of claim 7, wherein the wet etching is performed using TMAH or KOH (potassium hydroxide).

12. The method of claim 7, wherein the first developing pattern forms a first connection part connected to a manifold,
the second developing pattern forms a second connection part connected to a pressure chamber, and
the third developing pattern forms a restrictor part.

13. An inkjet print head comprising:
a first substrate in which a manifold and a pressure chamber are formed; and
a second substrate in which a first connection part connected to the manifold, a second connection part connected to the pressure chamber, and a restrictor part connecting the first connection part and the second connection part are formed,
wherein a boundary part connecting the restrictor part to the first connection part or the restrictor part to the second connection part is formed to be curved.

14. The inkjet print head of claim 13, further comprising a nozzle part formed to be spaced apart from the second connection part by a predetermined distance.

15. The inkjet print head of claim 13, wherein the second substrate is formed by dry etching and wet etching.
